(19) United States
(12) Patent Application Publication
(10) Pub. No.: US 2023/0325021 A1
(43) Pub. Date: Oct. 12, 2023

(54) PRESSURE SENSING APPARATUS AND ELECTRONIC DEVICE

(71) Applicant: SHENZHEN NEW DEGREE TECHNOLOGY CO.,LTD., Shenzhen, Guangdong (CN)

(72) Inventors: Hao LI, Shenzhen, Guangdong (CN); Weizhi LIU, Shenzhen, Guangdong (CN)

(21) Appl. No.: 18/024,462

(22) PCT Filed: Sep. 4, 2020
(86) PCT No.: PCT/CN2020/113537

§ 371 Date: Mar. 2, 2023

(51) Int. Cl. G06F 3/041; G01L 1/22

(52) U.S. Cl. CPC G06F 3/04144; G01L 1/2262

(57) ABSTRACT

A pressure sensing apparatus includes a substrate, a pressure sensor, a solder pad and a support. The pressure sensor and the solder pad are each disposed on the substrate. The solder pad can be welded to a panel of an electronic device. The solder pad is used for bearing a force signal and transmitting an electronic signal. The support is disposed on the lower surface of the substrate. By disposing the pressure sensor and the solder pad on the substrate, and directly mounting the pressure sensor beneath the panel by welding the solder pad to the panel, the installation of the pressure sensing apparatus has been generalized.

### TECHNICAL FIELD

This disclosure relates to the technical field of pressure sensing, and more particularly, relates to a pressure sensing apparatus and electronic device.

### BACKGROUND

At present, pressure sensing scheme for a track pad comprises pressure sensing feedback performed with a beam load cell, a piezoelectric pressure sensor and the like, in which the beam load cell is combined with a signal conditioning circuit and a microprocessor with a digital bus interface to form a beam load cell weighing system. The signal conditioning circuit is used for conditioning a signal output by the beam load cell, amplifying the output signal of the beam load cell and converting it into a digital signal, and then sending the digital signal to the microprocessor. Besides, when the beam load cell is used, one end of the load cell is secured and the other end is loaded with a to-be-tested product. Therefore, the beam load cell can only be installed with one end, which end is installed to the to-be-tested product, and it is inconvenient to assemble the beam load cell to the to-be-tested product, which is highly dependent on the structures, and the costs is too high for extensive use.

### SUMMARY

### Technical Problem

One objective of the embodiments of this disclosure is to provide a pressure sensing apparatus and electronic device, for solving the technical problems of existing beam load cells of high dependency on structures, inconvenience in assembly and high costs.

### TECHNICAL SOLUTION TO THE PROBLEM

### Technical Solution

To solve the above technical problems, the embodiments of this disclosure provide the following technical solutions:

In a first aspect, a pressure sensing apparatus is provided, which includes:
a substrate on which a detection circuit for detecting resistance change of a bridge circuit is provided;
a pressure sensor disposed on an upper surface and/or a lower surface of the substrate and electrically connected to the detection circuit;
a solder pad disposed on the upper surface of the substrate and electrically connectable to a panel of an electronic device, where the solder pad is used for bearing a force signal and transmitting an electronic signal;
a support disposed on the lower surface of the substrate for supporting the substrate.

In one embodiment, the pressure sensor is one of a plurality of pressure sensors, and the plurality of pressure sensors are electrically connected therebetween.

In one embodiment, the pressure sensor is provided with at least one channel.

In one embodiment, the solder pad is one of a plurality of solder pads, and the plurality of solder pads are spaced apart along an edge of the upper surface.

In one embodiment, the solder pad is welded to the panel through surface mounting.

In one embodiment, a shape of a cross-section of the substrate is any one of a rectangle, a triangle or a cross shape.

In one embodiment, the substrate is a flexible circuit board, an aluminum substrate, a ceramic substrate, or an FR-4 circuit board.

In a second aspect, an electronic device is provided, which includes a panel and the pressure sensing apparatus according to any one of the above embodiments, where the solder pad of the pressure sensing apparatus is welded to the panel, and the solder pad is electrically connected to the electronic device.

In one embodiment, the electronic device further includes a base, which is connected to the support of the pressure sensing apparatus.

In one embodiment, the panel is a touch pad or a touch screen.

### BENEFICIAL EFFECT OF THIS DISCLOSURE

### Beneficial Effect

The beneficial effects of the pressure sensing apparatus provided by the embodiments of this disclosure are as follows: as compared with existing art, the pressure sensing apparatus of this disclosure, with an arrangement where a pressure sensor is disposed on a substrate, a solder pad is disposed on the substrate, the solder pad is welded to a panel of an electronic device, a support supports the substrate such that the pressure sensor is directly mounted beneath the panel, and the mounting structure of the solder pad enables the entire pressure sensing apparatus to be directly installed to the to-be-tested panel, avoids the problem that the installation of a beam load cell is highly dependent on structures because the load cell can only have one of its ends installed to a to-be-tested product, and the generality of the pressure sensing apparatus is improved. In addition, since the traditional beam load cells need to be customized according to different customers, the costs are high, while the pressure sensing apparatus of this disclosure is a standard product, which can be compatible with different customers use requirements, and therefore the manufacturing costs of the product are reduced and the product costs are low.

### BRIEF DESCRIPTION OF THE DRAWINGS

### Description of the Drawings

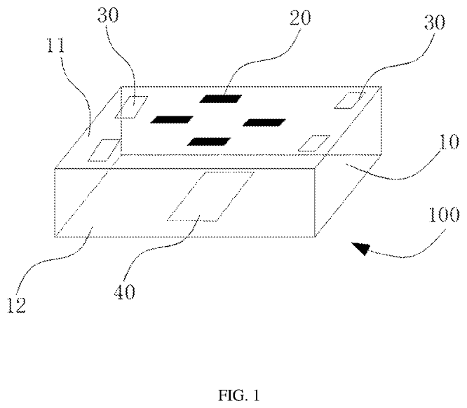

FIG. 1 is a schematic structural diagram of a pressure sensing apparatus according to one embodiment of this disclosure;

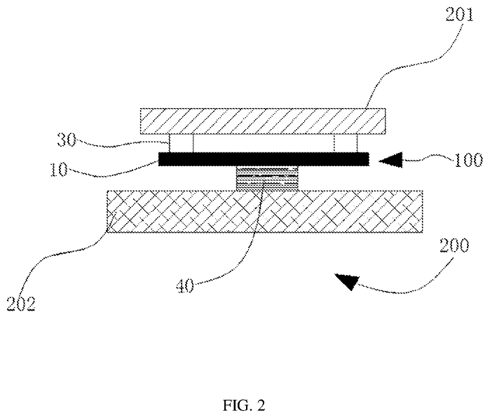

FIG. 2 is a schematic diagram of a pressure sensing apparatus installed on an electronic device according to one embodiment of this disclosure;

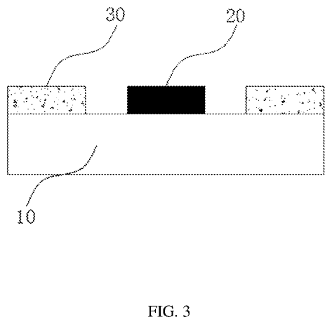

FIG. 3 is a schematic diagram of one installation of a pressure sensor and a substrate of a pressure sensing apparatus according to one embodiment of this disclosure;

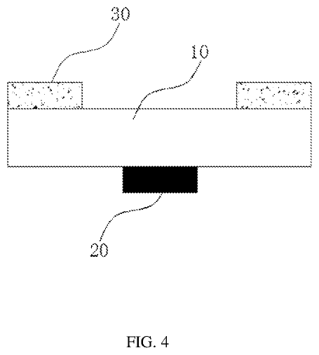

FIG. 4 is a schematic diagram of another installation of a pressure sensor and a substrate of a pressure sensing apparatus according to one embodiment of this disclosure;

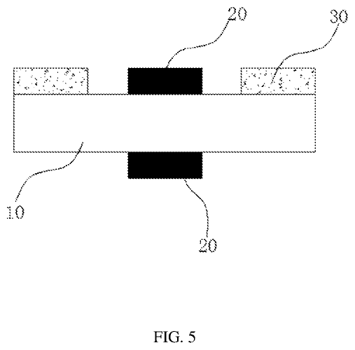

FIG. 5 is a schematic diagram of one installation of pressure sensors and a substrate of a pressure sensing apparatus according to one embodiment of this disclosure;

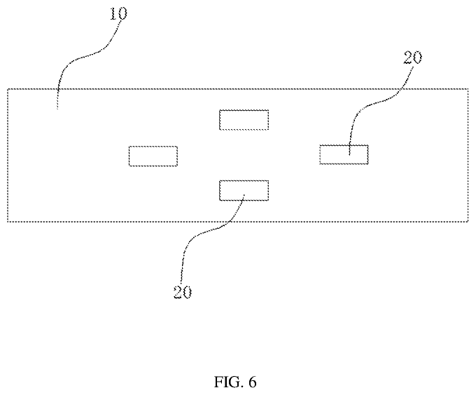

FIG. 6 is a schematic diagram of a single channel of pressure sensors of a pressure sensing apparatus according to one embodiment of this disclosure;

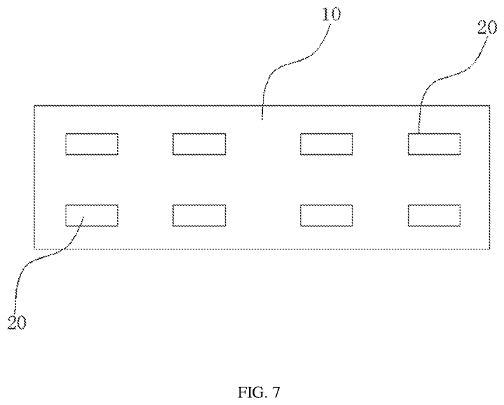

FIG. 7 is a schematic diagram of a dual channel of pressure sensors of a pressure sensing apparatus according to one embodiment of this disclosure;

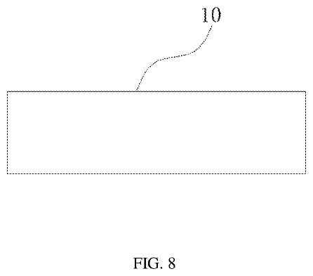

FIG. 8 is a schematic diagram of one structure of a substrate of a pressure sensing apparatus according to one embodiment of this disclosure;

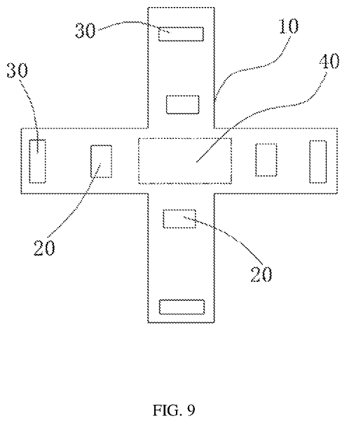

FIG. 9 is a schematic diagram of another structure of a substrate of a pressure sensing apparatus according to one embodiment of this disclosure;

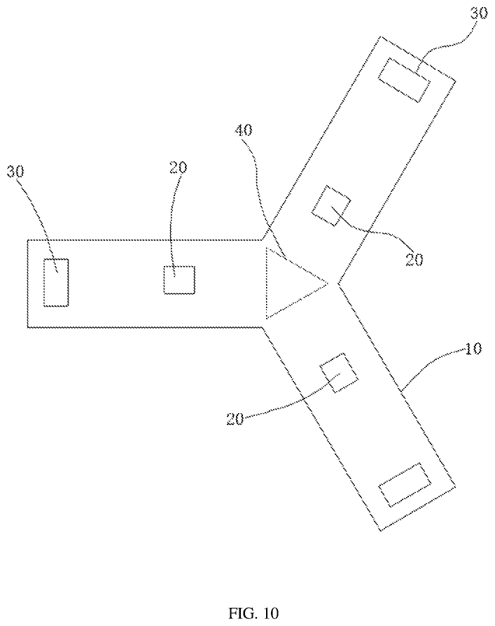

FIG. 10 is a schematic diagram of another Y-shaped structure of a substrate of a pressure sensing apparatus according to one embodiment of this disclosure;

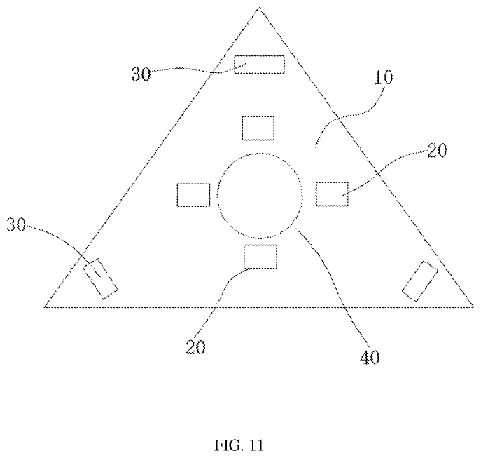

FIG. 11 is a schematic diagram of another structure of a substrate of a pressure sensing apparatus according to one embodiment of this disclosure;

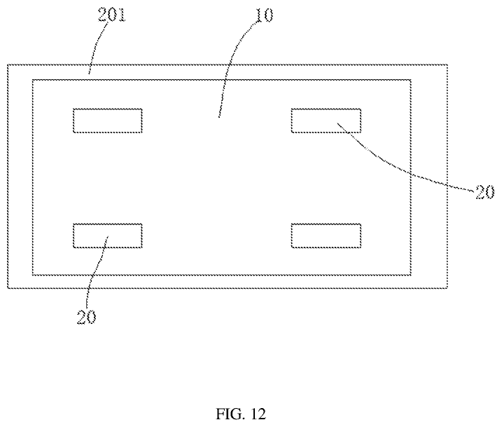

FIG. 12 is a partial schematic diagram of a pressure sensing apparatus installed on an electronic device according to one embodiment of this disclosure.

The reference numerals involved in the above-mentioned drawings are as follows:
100—pressure sensing apparatus;
10—substrate; 20—pressure sensor; 30—solder pad; 40—support;
11—upper surface; 12—lower surface;
200—electronic device; 201—panel; 202—base.

### DETAILED DESCRIPTION OF THE EMBODIMENTS

### Embodiments of this Disclosure

In order to make the technical problems, technical solutions and advantages of this disclosure clearer, this disclosure will be further described in detail below with reference to the accompanying drawings and embodiments. It should be understood that the specific embodiments described herein are merely illustrative of this disclosure and are not intended to limit this disclosure.

It should be noted that when an element is referred to as being “fixed at” or “provided in” another element, it may be on the other element directly or indirectly. When an element is referred to as being “coupled to” to another element, it may be connected to the other element directly or indirectly.

It should be understood that an orientation or positional relationship indicated by the terms “length”, “width”, “up”, “down”, “front”, “back”, “left”, “right”, “vertical”, “horizontal”, “top”, “bottom”, “inside”, “outside” and the like is an orientation or positional relationship shown in the drawings, and is merely for the convenience of describing this disclosure and simplifying the description, rather than indicating or implying that the device or elements referred to have a particular orientation, and are configured and operated along a particular orientation. Thus, it cannot be construed as limiting this disclosure.

In addition, terms “first” and “second” are only adopted for description and should not be understood to indicate or imply relative importance or implicitly indicate the number of indicated technical features. Therefore, a feature defined by “first” and “second” may explicitly or implicitly indicate inclusion of one or more of such features. In the description of this disclosure, “a plurality of” means two or more, unless otherwise limited definitely and specifically.

In order to illustrate the technical solutions of this disclosure, the following detailed description is made with reference to the specific accompanying drawings and embodiments.

As shown in FIG. 1 to FIG. 5, one embodiment of this disclosure provides a pressure sensing apparatus 100, which is applicable to an electronic device 200, and includes a substrate 10, a pressure sensor 20, a solder pad 30 and a support 40. A detection circuit is provided on the substrate for detecting resistance change of a bridge circuit. The pressure sensor 20 is disposed on the upper surface 11 and/or the lower surface 12 of the substrate 10, and the pressure sensor 20 is electrically connected to the detection circuit. The solder pad 30 is disposed on the upper surface 11 of the substrate 10 and may be welded to a panel 201 of the electronic device 200, and the solder pad 30 is electrically connected to the electronic device 200. Specifically, the solder pad 30 is electrically connected to the substrate 10, the substrate 10 is electrically connected to the electronic device 200, and the solder pad 30 is used for bearing a force signal and transmitting an electronic signal. The support 40 is disposed on the lower surface 12 of the substrate 10 for supporting the substrate 10.

The pressure sensing apparatus 100 provided in this embodiment, with an arrangement where the pressure sensor 20 is disposed on the substrate 10, the solder pad 30 is disposed on the substrate 10, the solder pad 30 is welded to the panel 201 of the electronic device 200, the support 40 supports the substrate 10 such that the pressure sensor 20 is directly mounted beneath the panel 201, and the mounting structure of the solder pad 30 enables the entire pressure sensing apparatus 100 to be directly installed to the to-be-tested panel 201, avoids the problem that the installation of a beam load cell is highly dependent on structures because the load cell can only have one of its ends installed to a to-be-tested product. In addition, with the pressure sensor 20 being mounted on the substrate 10 and with the solder pad 30 being welded to the panel 201 of the electronic device 200, all the pressures, when applied to the panel 201 during use, will fully act on the pressure sensing apparatus 100, thereby the measurement sensitivity is improved. In addition, since the traditional beam load cells need to be customized according to different customers, the costs are high, while the pressure sensing apparatus 100 of this disclosure is a standard product, which can be compatible with different customers use requirements, and the costs are low.

In some embodiments of this disclosure, optionally, as shown in FIG. 1, FIG. 3 to FIG. 5, there are a plurality of pressure sensors 20, and the plurality of sensors are electrically connected therebetween.

In this embodiment, a plurality of pressure sensors 20 may be provided. The plurality of pressure sensors 20 are disposed on the upper surface 11 of the substrate 10, or the plurality of pressure sensors 20 are disposed on the lower surface 12 of the substrate 10, or the plurality of pressure sensors 20 may be disposed both on the upper surface 11 and on the lower surface 12 of the substrate 10, so as to improve the measurement sensitivity of the pressure sensing apparatus 100 during the measurements. Alternatively, one pressure sensor 20 may be disposed on the upper surface 11 of the substrate 10, or one pressure sensor 20 may be disposed on the lower surface 12 of the substrate 10, depending on the requirement of the to-be-tested electronic device 200.

It should be noted that, in addition to a non-destruction testing (NDT) micro-pressure strain sensor, the pressure sensor 20 may be this structure of other pressure sensitive materials such as metal wire strain gauge, silicon wafer strain gauge, polycrystalline or amorphous semiconductor, copper-nickel alloy, carbon nanotube, graphene, piezoelectric ceramic, and conductor-insulator composite material, etc. The pressure sensors 20 may be electrically connected therebetween with all conductive materials such as Cu (copper), Ag (silver), carbon paste, and etc.

In some embodiments of this disclosure, optionally, as shown in FIG. 6 and FIG. 7, the pressure sensors 20 are provided with at least one channel.

In this embodiment, the channel of the pressure sensors 20 may be configured with a single-channel signal transmission mode as shown in FIG. 6, or may be configured with a dual-channel signal transmission mode as shown in FIG. 7. Alternatively, the pressure sensors 20 may be configured with a multi-channel signal transmission mode, and specifically, the number of channels may be set according to requirements of the to-be-tested electronic device 200.

In some embodiments of this disclosure, optionally, as shown in FIG. 1 to FIG. 5, a plurality of solder pads 30 are provided, and the plurality of solder pads 30 are disposed along an edge of the upper surface 11.

In this embodiment, a plurality of solder pads 30 may be provided. For example, the cross-section of the substrate 10 is rectangular, that is, the substrate 10 is a cube. Four solder pads 30 are provided, where two solder pads 30 of the four solder pads 30 are disposed at the left side of the upper surface 11 of the substrate 10, and the other two solder pads 30 are disposed at the right side of the upper surface 11 of the substrate 10, such that the connection between the panel 201 and the pressure sensing apparatus 100 is more solid when the solder pads 30 are welded to the panel 201 of the electronic device 200. Besides, when the panel 201 is touched, the solder pads 30 may bear the force signals and transmit the electronic signals through the welding points with the panel 201. Optionally, the solder pads 30 are welded to the panel 201 by means of SMT process.

In the foregoing embodiments of this disclosure, optionally, the solder pads 30 may be welded to the panel 201 through surface mounting. By using surface mounting technology, the solder pads 30 can be welded to the panel 201 through surface mounting, so as to secure the pressure sensing apparatus 100 on the panel 201 of the electronic device 200.

In some embodiments of this disclosure, optionally, as shown in FIG. 8 to FIG. 11, the shape of the cross-section of the substrate 10 is any one of a rectangle, a triangle, a cross shape, or a Y shape.

In this embodiment, the shape of the substrate 10 may be configured to be any one of a rectangle, a triangle, or a cross shape. Of course, the substrate 10 may also be in other shapes. As shown in FIG. 10, the three supporting plates of the substrate 10 are 120° from each other. Specifically, the shape of the substrate 10 can be configured to match the shape of the panel 201 of the electronic device 200.

In some embodiments of this disclosure, optionally, the substrate 10 is a flexible circuit board, an aluminum substrate, a ceramic substrate, or an FR-4 circuit board.

In this embodiment, the substrate 10 may be selected from a flexible circuit board, an aluminum substrate, a ceramic substrate, or an FR-4 circuit board. Specifically, the substrate 10 is made of a metal circuit board, such as an aluminum substrate, or made of materials such as plastic, ceramic, and sheet glass.

As shown in FIG. 2 and FIG. 12, another embodiment of this disclosure provides an electronic device 200, which includes a panel 201 and the pressure sensing apparatus 100 according to any one of the above embodiments. The solder pad(s) 30 of the pressure sensing apparatus 100 is welded to the panel 201, and the solder pad(s) 30 is electrically connected to the electronic device 200.

Specifically, the solder pad(s) 30 of the pressure sensing device 100 is welded to the panel 201 through SMT process, and the solder pad(s) 30 simultaneously bears a force signal and transmits an electrical signal. In addition, a plurality of pressure sensing apparatuses 100 may be welded on the panel 201 via the solder pads 30 through SMT process.

As shown in FIG. 12, the pressure sensing apparatus 100 is installed on a panel 201 of a track pad. The panel 201 is welded to the substrate 10 via the solder pads 30 (not shown), and a plurality of pressure sensors 20 are disposed on the substrate 10. The number of the pressure sensors 20 on the substrate 10 may be configured according to actual needs. When the panel 201 is pressed, electrical signals are output by each pressure sensors 20 for determination of the actual pressure value, pressure position and gesture information, with a specific algorithm same as the algorithm for the existing pressure sensors, which will not be repeated here.

It should be noted that, the electronic device 200 may be a track pad, or may be an electronic display screen, or may be a smartphone or the like, and the panel 201 may be a touch pad or a touch screen.

In some embodiments of this disclosure, optionally, the electronic device 200 further includes a base 202, which is connected to a support 40 of the pressure sensing apparatus 100, as shown in FIG. 2.

In this embodiment, the solder pads 30 of the pressure sensing apparatus 100 is welded to the panel 201 through surface mounting technology, and then the support 40 is connected to the base 202, thereby the pressure sensing apparatus 100 is installed on the electronic device 200. The support 40 may be a connector made of flexible material, and may also be a connector made of rigid material, for example, a nut welded to the lower surface 12 of the substrate 10 through SMT process, or may be directly connected to the base 202 by means of glue, VHB (Very High Bond) polyacrylate double-sided foam tape, double-sided adhesive, various adhesive dispenses.

The pressure sensing apparatus 100 provided in this disclosure may be applied to a to-be-tested product, which may be an electronic device 200, with the following operations:

disposing the pressure sensor(s) 20 on the upper surface 11 and/or the lower surface 12 of the substrate 10 to form the detection circuit, and connecting the solder pad(s) 30 on the upper surface 11 of the substrate 10 such that the solder pad(s) 30 is welded to the panel 201 of the electronic device 200, and then connecting the support 40 with the base 202 of the electronic device 200, where one or more pressure sensing apparatuses 100 may be arranged between the panel 201 and the base 202, and all the pressures, when applied to the panel 201 during use, will fully act on the pressure sensing apparatus 100, thereby the measurement sensitivity is improved.

In summary, when implemented, the pressure sensing apparatus provided in the embodiments has at least the following beneficial technical effects over existing art: the pressure sensing apparatus, with an arrangement where a pressure sensor is disposed on a substrate, a solder pad is disposed on the substrate, the solder pad is welded to a panel of an electronic device, a support supports the substrate such that the pressure sensor is directly mounted beneath the panel, and the mounting structure of the solder pad enables the entire pressure sensing apparatus to be directly installed to the to-be-tested panel, avoids the problem that the installation of a beam load cell is highly dependent on structures because the load cell can only have one of its ends installed to a to-be-tested product. Besides, all the pressures, when applied to the panel, will fully act on the pressure sensing apparatus, thereby the measurement sensitivity is improved.

The above are merely alternative embodiments of this disclosure, and are not intended to limit this disclosure. Any modification, equivalent replacement, improvement, etc. made within the spirit and principle of this disclosure should be included within the protection scope of this disclosure.

1. A pressure sensing apparatus, applicable to an electronic device, and comprising:
a substrate on which a detection circuit for detecting resistance change of a bridge circuit is provided;
a pressure sensor disposed on an upper surface and/or a lower surface of the substrate and electrically connected to the detection circuit;
a solder pad disposed on the upper surface of the substrate and electrically connectable to a panel of the electronic device, wherein the solder pad is used for bearing a force signal and transmitting an electronic signal; and
a support disposed on the lower surface of the substrate for supporting the substrate.

2. The pressure sensing apparatus according to claim 1, wherein the pressure sensor is one of a plurality of pressure sensors, and the plurality of pressure sensors are electrically connected therebetween.

3. The pressure sensing apparatus according to claim 1, wherein the pressure sensor is provided with at least one channel.

4. The pressure sensing apparatus according to claim 1, wherein the solder pad is one of a plurality of solder pads, and the plurality of solder pads are spaced apart along an edge of the upper surface.

5. The pressure sensing apparatus according to claim 1, wherein the solder pad is welded to the panel through surface mounting.

6. The pressure sensing apparatus according to claim 1, wherein a shape of a cross-section of the substrate is any one of a rectangle, a triangle or a cross shape.

7. The pressure sensing apparatus according to claim 1, wherein the substrate is a flexible circuit board, an aluminum substrate, a ceramic substrate, or an FR-4 circuit board.

8. An electronic device, comprising a panel and a pressure sensing apparatus comprising:
a substrate on which a detection circuit for detecting resistance change of a bridge circuit is provided;
a pressure sensor disposed on an upper surface and/or a lower surface of the substrate and electrically connected to the detection circuit;
a solder pad disposed on the upper surface of the substrate and electrically connectable to the panel of the electronic device, wherein the solder pad is used for bearing a force signal and transmitting an electronic signal; and
a support disposed on the lower surface of the substrate for supporting the substrate, wherein the solder pad of the pressure sensing apparatus is welded to the panel, and the solder pad is electrically connected to the electronic device.

9. The electronic device according to claim 8, further comprising a base, which is connected to the support of the pressure sensing apparatus.

10. The electronic device according to claim 8, wherein the panel is a touch pad or a touch screen.

11. The electronic device according to claim 8, wherein the pressure sensor is one of a plurality of pressure sensors, and the plurality of pressure sensors are electrically connected therebetween.

12. The electronic device according to claim 8, wherein the pressure sensor is provided with at least one channel.

13. The electronic device according to claim 8, wherein the solder pad is one of a plurality of solder pads, and the plurality of solder pads are spaced apart along an edge of the upper surface.

14. The electronic device according to claim 8, wherein the solder pad is welded to the panel through surface mounting.

15. The electronic device according to claim 8, wherein a shape of a cross-section of the substrate is any one of a rectangle, a triangle or a cross shape.

16. The electronic device according to claim 8, wherein the substrate is a flexible circuit board, an aluminum substrate, a ceramic substrate, or an FR-4 circuit board.

17. The electronic device according to claim 11, further comprising a base, which is connected to the support of the pressure sensing apparatus.

18. The electronic device according to claim 12, further comprising a base, which is connected to the support of the pressure sensing apparatus.

19. The electronic device according to claim 13, further comprising a base, which is connected to the support of the pressure sensing apparatus.

20. The electronic device according to claim 14, further comprising a base, which is connected to the support of the pressure sensing apparatus.
